(19) United States
(12) Patent Application Publication
(10) Pub. No.: US 2003/0075715 A1
(43) Pub. Date: Apr. 24, 2003

(54) Thin film transistor

(75) Inventors: Masaharu Satoh, Tokyo (JP); Kentaro Nakahara, Tokyo (JP); Jiro Iriyama, Tokyo (JP); Shigeyuki Iwasa, Tokyo (JP); Yukiko Morioka, Tokyo (JP)

Correspondence Address: McGinn & Gibb, PLLC, Suite 200, 8321 Old Courthouse Road, Vienna, VA, 22182-3817, US

(73) Assignee: NEC Corporation, Tokyo (JP)

(21) Appl. No.: 10/230,325

(22) Filed: Aug. 29, 2002

(30) Foreign Application Priority Data
Sep. 19, 2001 (JP) 2001-285513

(51) Int. Cl. H01L 35/24

(52) U.S. Cl. 257/40

(57) ABSTRACT

The thin film transistor (10) comprises a source region (14), a drain region (15), a channel forming region (16) between the source and drain regions, and a gate electrode (12). In this thin film transistor 10, the channel forming region (16) is composed of an organic compound having a radical.

### BACKGROUND OF THE INVENTION

1. Field of the Invention

The present invention relates to a thin film transistor (TFT), and more particularly to a thin film transistor enhanced in both carrier mobility and on/off ratio.

2. Related Art

A thin film transistor is formed on a substrate such as a glass board, and comprises a source region, a drain region, a channel forming region between the source and drain regions, and a gate electrode corresponding to the channel forming region. Such thin film transistor is used, for example, as a switching device for a liquid crystal display, and the channel forming region is usually made of a semiconductor such as amorphous silicone or polycrystalline silicon.

On the other hand, a thin film transistor which can be formed on a plastic substrate is also attracting attention. Such thin film transistor can be also used in a thin, lightweight, and foldable display, but an ordinary inorganic semiconductor which requires high temperature process in thin film forming cannot be used. Accordingly, as the material for channel forming region, organic materials which are easy to process and are excellent in affinity for plastic substrate are being studied.

The material for forming the channel forming region is required to have a certain level of carrier mobility and on/off ratio, but few organic materials satisfy both carrier mobility (μ) and on/off ratio.

Herein, the term “on/off ratio” refers to the ratio of the source-drain current (IDS) when the transistor is on, to the source-drain current when the transistor is off. The carrier mobility is the scale of the average drift speed of particles (for example, electrons or positive holes) in a layer formed by a channel forming material, and it is important to determine how much effect such particle motion receives depending on the applied electric field. The conductivity (σ) shows the capability of the semiconductor material layer for conducting the electric charge. The conductivity is related to the carrier mobility (μ) in the following formula.

σ=qpμ

(where p: carrier density, q: elementary electric charge)

So far, as the method of manufacturing thin film transistors using organic materials in the channel forming regions, three methods have been mainly studied, that is, electrolytic polymerization, solution coating, and vacuum deposition. Tsumura, A. et al., in “Macromolecular electronic device: Field-effect transistor with a polythiophene thin film”, Appl. Phys. Lett., vol. 49 (18), pp. 1210-1212 (1986), teach that a polythiophene compound of carrier mobility of about 10⁻⁵/cm²/Vsec is obtained by electrolytic polymerization of 2,2′-bithiophene and tetraethyl ammonium perchlorate in an acetonitrile solution. However, the polythiophene compound is too low in its carrier mobility to be used as a material for thin film transistor.

According to Assadi, A. et al., “Field-effect mobility of poly (3-hexylthiophene)”, Appl. Phys. Lett., vol. 53 (3), pp. 195-197 (1988), poly (3-hexylthiophene) is dissolved in chloroform at concentration of 1 mg/ml, and applied on a substrate by spin coating, and an amorphous poly (3-alkylthiophene) semiconductor macromolecular film is formed. In this material, too, the carrier mobility is about 10⁻⁵ cm²/Vsec to 10⁻⁴ cm²/Vsec, and the value is too small to be used as the material for thin film transistor.

Fuchigami, H. et al., in “Polythienylenevinylene thin film transistor with high carrier mobility”, Appl. Phys. Lett., vol. 63 (10), pp. 1372-1374 (1993), teach that polythienylenevinylene is formed from a soluble precursor of polymer. That is, after depositing the precursor polymer in the solution, it is converted into a semiconductor polymer capable of forming a channel by chemical reaction. The carrier mobility of the organic semiconductor polymer formed by employing this two-step process is about 10⁻¹ cm²/Vsec.

Further, an organic semiconductor polymer formed by vacuum deposition method of oligomer such as oligothiophene is disclosed by Garnier, F. et al., “All-Polymer Field-Effect Transistor Realized by Printing Techniques”, Science, vol. 265, pp. 1684-1686 (1994). The carrier mobility of the organic semiconductor polymer discussed in this publication is about 10⁻²cm²/Vsec, and the value is slightly large, but nothing is mentioned about the on/off ratio, and its thin film forming process is far from simple.

Incidentally, methods of synthesis of organic compounds such as macromolecular compounds by using radicals are being developed, and are applied in production of various materials. However, the radicals are generally high in reactivity as compared with other chemical reactions, their control is difficult, and radical compounds produced by radical reactions are unstable, and hence so far little has been attempted to apply radicals in electronic devices such as thin film transistors.

Any substance is, however, unstable in some part or the other, and close investigations will reveal presence of radicals, more or less, as nonbonding elements in an actual material. In particular, in conductive high polymers such as polythiophene or polythienylenevinylene given above, when doping with an electron-accepting or electron-donating compound, charged radicals such as solitons and polarons are generated, and the spin concentration may reach as high as 10¹⁸ spins/g. In this case, the conductivity of the conductive high polymer increases, together with the increase in spin concentration, in an exponential function, and therefore it cannot be used as the material for channel forming region, for example, in a thin film transistor.

In this case, the “radical reaction” refers to a chemical reaction in which a radical is participated, and it is defined particularly in this specification to include both the reaction of producing a radical compound from a nonradical compound in at least one process of electrochemical oxidation or reduction, and the reaction of converting the produced radical compound into a nonradical compound.

Thus, the thin film transistors are preferably used in various applications, but materials usable for channel forming regions to be formed on a thin, lightweight, and flexible plastic substrate are limited. As the materials for channel forming regions, organic materials which are easy to process and excellent in affinity for plastic substrate are being studied, but it was difficult to obtain organic materials satisfying both required carrier mobility and on/off ratio, in a simple method and at a low cost.

The invention is devised in the light of the background discussed above, it is hence an object thereof to present a thin film transistor which satisfies both required carrier mobility and on/off ratio, and has a carrier forming region formed by a material obtained by a simple and inexpensive method.

### SUMMARY OF THE INVENTION

To achieve the object, the thin film transistor comprising a source region, a drain region, a channel forming region provided between the source region and the drain region, and a gate electrode provided corresponding to the channel forming region, wherein the channel forming region is composed of an organic compound having a radical.

In the specification, the “radical compound” refers to a chemical species having an unpaired electron, that is, a chemical species having an electron not forming an electron pair, and in other words it is a compound having a radical, and since the spin nucleus momentum is not zero, it has a magnetic property similar to paramagnetism. The “organic compound” in the specification refers collectively to all carbon compounds such as oxide of carbon and carbonate of melt, except for few simple ones, and the “organic macromolecular compound” refers to an organic compound with a molecular weight of 10,000 or more, having its main chain formed mainly by covalent bond.

In the thin film transistor of the present invention, an organic compound having a radical, that is, a radical compound having an unpaired electron is used as the material for channel forming region, and hence transition of electrons is possible from single occupied molecular orbit (SOMO) to highest occupied molecular orbit (HOMO). As a result, the carrier concentration is heightened, hopping of excited carrier is possible, so that the thin film transistor satisfying desired values of both carrier mobility and on/off ratio can be obtained. Further by the magnitude of the gate voltage, the organic compound of radical compound can be converted into a reaction product, that is, radical or oxidation-reduction product, so that memory effects can be provided in the thin film transistor.

Generally, radicals are produced when the chemical bond of molecule is cleaved by pyrolysis, photolysis, radiolysis, or electron exchange. Radicals are insulators of an extremely high chemical reactivity, and the reactivity varies quickly by reaction between radicals or with other unstable molecule. The presence of such radicals can be observed by measurement of electron spin resonance spectrum (ESR spectrum) or the like.

When composing the thin film transistor of the present invention, the spin concentration of the organic compound having a radical is preferred to be 10¹⁹ spins/g or more, and more preferably 10²⁰ spins/g or more. In this composition, the on/off ratio of the thin film transistor can be easily enhanced.

Also, when composing the thin film transistor of the present invention, the organic compound having a radical is preferred to be composed of an organic macromolecular compound having a radical. In this composition, a uniform channel forming region excellent in flexibility is obtained, and a thin film transistor excellent in stability is obtained.

More specifically, the material for the organic compound having a radical includes, among others, nitroxide radical, oxygen radical, nitrogen radical, carbon radical, sulfur radical, or boron radical. When the organic compound is made of a nitroxide radical material, although the carrier concentration is lower than in other radicals, the on/off ratio is greater, and it is stable in the air. When the organic compound is made of an oxygen radical material, the carrier concentration is higher than in other radicals. When the organic compound is made of a nitrogen radical material, since the radical is stabilized in the molecule, the on/off ratio is large and the stability is excellent, and when the organic compound is made of a carbon radical material, since the SOMO level is low, as compared to other radicals, the temperature dependence of carrier concentration and mobility is smaller and is stable. When the organic compound is made of a sulfur radical or boron radical material, although the on/off ratio is low, the concentration and mobility are higher.

### BRIEF DESCRIPTION OF THE DRAWING

FIG. 1 is a sectional view showing a configuration of a thin film transistor in a preferred embodiment of the present invention.

### DESCRIPTION OF THE PREFERRED EMBODIMENTS

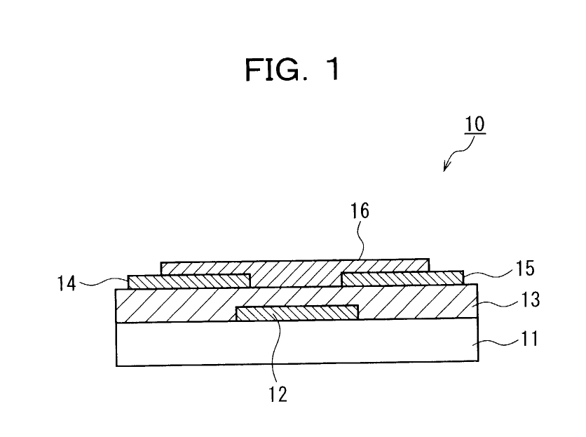

Referring now to the drawing, a preferred embodiment of the invention is specifically described below. FIG. 1 is a sectional view showing a configuration of a thin film transistor in a preferred embodiment of the invention.

In a thin film transistor 10 of the embodiment, on an insulating surface of a glass board 11, a gate electrode 12 and a gate insulating film 13 are formed in this sequence, and a source region 14 and a drain region 15 are formed so as to be positioned at both sides of the gate electrode 12 on the gate insulating film 13. On both regions 14, 15 including a space between the source region 14 and drain region 15, a channel forming region 16 made of an organic compound having a radical is formed.

This thin film transistor 10 has functions of an ordinary transistor such as amplifying action and switching action, and it can be used, for example, as a switching element for an active matrix liquid crystal device.

In the thin film transistor of the invention, not limited to the configuration described herein, the lamination structure can be varied as required. For example, a transistor of a reverse staggered structure may be composed by laminating the gate electrode 12, gate insulating film 13, channel forming layer 16, and source and drain regions 14, 15 sequentially on the glass board 11. Or, instead of the glass board 11, a silicon substrate may be prepared, and a silicon gate type transistor may be composed by forming the gate electrode 12 and source and drain regions 14, 15 on this silicon substrate, and further forming the channel forming layer 16 to cover the source and drain regions 14, 15. Moreover, by disposing the gate electrode 12 and source and drain regions 14, 15 through the channel forming layer (16), a Schottky barrier gate type transistor may be composed.

In this embodiment, the type of the organic compound having a radical as the material for the channel forming region is not particularly limited as far as it is an organic compound having a radical. However, considering from the excellent actions and effects obtained and also an excellent processability, as the organic compound, it is preferred to use an organic compound expressed in formula (1) below, an organic compound expressed in formula (2), or an organic compound including a structural unit expressed in either formula (1) or (2).

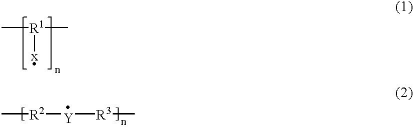

In formula (1), substituent R¹ is substituted or non-substituted alkylene group, alkenylene group, or arylene group, and X is oxy radical group, nitroxyl radical group, sulfur radical group, hydrazyl radical group, carbon radical group, or boron radical group.

In formula (2), substituents R² and R³ are mutually independent, and are substituted or non-substituted alkylene group, alkenylene group, or arylene group, and Y is nitroxyl radical group, sulfur radical group, hydrazyl radical group, or carbon radical group.

Examples of such radical compound include, among others, oxy radical compound, nitroxyl radical compound, carbon radical compound, nitrogen radical compound, boron radical compound, and sulfur radical compound.

Specific examples of the oxy radical compound include aryloxy radical compounds expressed in formula (3), and formula (4), and a semiquinone radical compound expressed in formula (5).

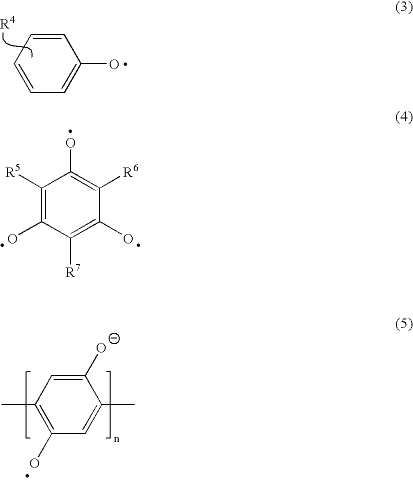

In formulae (3) to (5), substituents R4 to R7 are mutually independent, and are hydrogen atom, substituted or non-substituted aliphatic group, or aromatic hydrocarbon group, halogen group, hydroxyl group, nitro group, nitroso group, cyano group, alkoxy group, aryloxy group, or acyl group.

Specific examples of the nitroxyl radical compound include a radical compound having a pyperidinoxy ring expressed in formula (6), a radical compound containing pyrrolidinoxy ring expressed in formula (7), a radical compound containing pyrrolinoxy ring expressed in formula (8), and a radical compound containing nitronyl nitroxide structure expressed in formula (9).

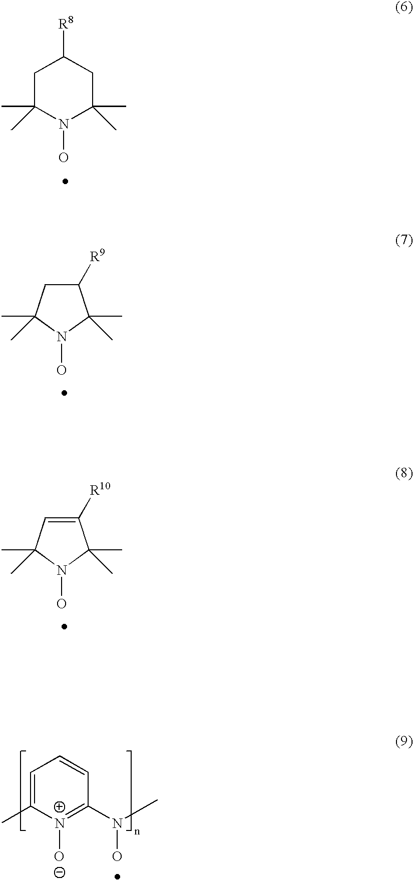

In formulae (6) to (9), R⁸ to R¹⁰ are same as in formulae (3) to (5).

Specific examples of the nitrogen radical compound include a radical compound having a trivalent hydrazyl group expressed in formula (10), a radical compound having a trivalent ferrudazyl group expressed in formula (11), and a radical compound having an aminotriazine structure expressed in formula (12).

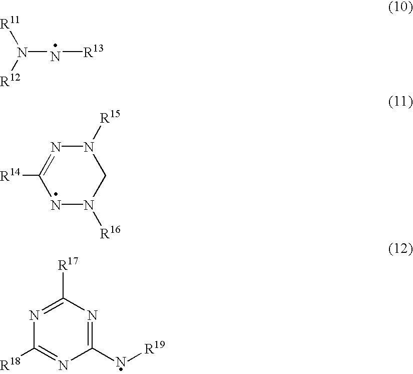

In formulae (10) to (12), R¹¹ to R¹⁹ are same as in formulae (3) to (5).

In the embodiment, such radical compounds can be used directly as the material for the channel forming region, or as material for the channel forming region by combining with other high polymer or low polymer organic material or inorganic material.

As mentioned above, in such “radical compound”, the spin nucleus momentum thereof is not zero, but “radical compound” exhibit various magnetic properties such as paramagnetism, and therefore generation of the unpaired electrons can be observed by measuring the ESR spectrum or the like. In the present invention, however, even if the signal can be obtained by the ESR spectrum, such organic compound is not called a radical compound if electrons are non-localized. Compounds having non-localized electrons include conductive high polymers forming soliton or polaron, but the spin concentration thereof is low, and it is generally 10¹⁹ spins/g or less.

Thus, in the thin film transistor of the embodiment, since the organic compound having a radical is used as the material for the channel forming region, transition of electrons is possible from single occupied molecular orbit (SOMO) to highest occupied molecular orbit (HOMO). As a result, the carrier concentration becomes higher, hopping of excited carrier is also enabled. Accordingly, the thin film transistor satisfying the desired values of both carrier mobility and on/off ratio can be obtained. Further by the magnitude of the gate voltage, the organic compound of radical compound can be converted into a reaction product, that is, radical or oxidation-reduction product, so that memory effects can be provided in the thin film transistor.

(Embodiments)

The present invention is more specifically described below, but it must be noted that the invention is not limited to these embodiments alone.

(Embodiment 1)

A product obtained by radical polymerization of 2,2,6,6-tetramethyl piperidine methacrylate was oxidized in m-chloroperbenzoic acid, and poly (2,2,6,6-tetramethyl piperidinoxy methacrylate) radical shown in formula 13 was synthesized. The obtained poly (2,2,6,6-tetramethyl piperidinoxy methacrylate) radical was a brown macromolecular solid, with the average molecular weight of 89000, and the spin concentration measured by the ESR spectrum was 2×10²¹ spins/g.

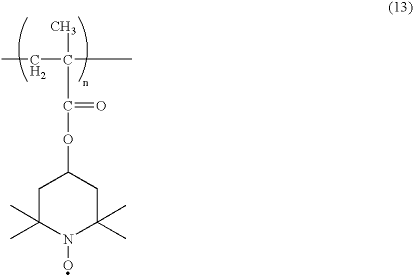

Next, chromium was evaporated in an alkali-free glass substrate through a mask, and a gate electrode of 100 nm in thickness was obtained. On this gate electrode, a silicon nitride film of 400 nm in thickness was formed as a gate insulating film by the CVD method, and chromium was evaporated on the gate insulating film in a film thickness of 20 nm through a mask. In succession, gold was evaporated in a film thickness of 50 nm, and a source electrode (region) and a drain electrode (region) were formed, and an element before fabrication of channel forming region was formed.

Between the source electrode (region) and drain electrode (region) of the element, a tetrahydrofuran solution of the poly (2,2,6,6-tetramethyl piperidinoxy methacrylate) radical was dripped, and the both electrodes were covered including the gap between the two electrode, and this solvent was dried in air. Thus was obtained the thin film transistor using the organic layer composed of poly (2,2,6,6-tetramethyl piperidinoxy methacrylate) radical as the channel forming region. In this trial product of the thin film transistor, the channel width was 24 mm, and the channel length was 1 mm.

Using this thin film transistor, at a constant drain voltage (Vd), the dependence of the source current (Is) flowing in the source electrode on the gate voltage (Vg) (Is-Vg characteristic), and the dependence of the source current (Is) on the drain voltage (Vd) at a constant Vg (Is-Vd characteristic) were measured.

Using the measured results, the saturation current Isat was determined from the Is-Vd characteristic, and d/dVg was determined from the inclination of the Is^{½}-Vg characteristic, and the field effect mobility m_{FE} was calculated in the following formula.

(d/dVg) Isat^{½}={(W/2L)Ci m_{FE}}^{½}

where W and L are channel width and length, respectively, and Ci is the capacitance of the gate insulating layer. As a result of the calculation, the field effect mobility of the prepared thin film transistor was 1×10^{31 3} cm²/Vsec, and the on/off ratio was 10³ or more. Hence, the thin film transistor of the embodiment was found to be excellent.

(Embodiment 2)

A product obtained by cationic polymerization of 2,6-ditertiary butyl-4-vinyl phenol by using BF₃.O (C₂H₅)₂ was oxidized in m-chloroperbenzoic acid, and poly (2,6-ditertiary butyl-4-vinyl phenol) radical shown in formula 14 was synthesized. The obtained poly (2,6-ditertiary butyl-4-vinyl phenol) radical was a red macromolecular solid, and the spin concentration measured by ESR spectrum was 1×10²¹ spins/g.

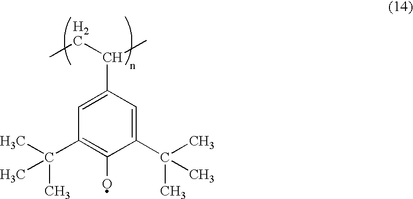

Next, instead of the poly (2,2,6,6-tetramethyl piperidinoxy methacrylate) radical in embodiment 1, an acetonitrile solution of the poly (2,6-ditertiary butyl-4-vinyl phenol) radical obtained in this process was dripped on the element before fabrication of the channel forming region of embodiment 1 same as in embodiment 1, and it was dried in air. Thus was obtained the thin film transistor using the organic layer composed of poly (2,6-ditertiary butyl-4-vinyl phenol) radical as the channel forming region.

Using this thin film transistor, the Is-Vg characteristic and Is−Vd characteristic were measured in the same manner as in embodiment 1, and the field effect mobility and on/off ratio were determined. As a result, the field effect mobility of the prepared thin film transistor was 5×10⁴ cm²/Vsec, and the on/off ratio was 10⁴ or more. Hence, the thin film transistor of the embodiment was also found to be excellent.

(Embodiment 3)

A copolymer of the poly (2,2,6,6-tetramethyl piperidinoxy methacrylate) radical in embodiment 1 and vinylidene fluoride/tetrafluoroethylene (copolymerization ratio 70/30) dissolved in tetrahydrofuran at a ratio of 1/1 by mass, a solution with polymer concentration of 1 wt. % was prepared.

Next, instead of the poly (2,2,6,6-tetramethyl piperidinoxy methacrylate) radical in embodiment 1, a solution of a complex of a copolymer of the poly (2,2,6,6-tetramethyl piperidinoxy methacrylate) radical and vinylidene fluoride/tetrafluoroethylene obtained in the above process was similarly dripped on the element before fabrication of the channel forming layer in embodiment 1, it was dried in air. Thus was obtained the thin film transistor using the organic layer composed of a complex of a copolymer of the poly (2,2,6,6-tetramethyl piperidinoxy methacrylate) radical and vinylidene fluoride/tetrafluoroethylene as the channel forming region.

Using this thin film transistor, the Is-Vg characteristic and Is-Vd characteristic were measured in the same manner as in embodiment 1, and the field effect mobility and on/off ratio were determined. As a result, the field effect mobility of the prepared thin film transistor was 4×10⁻⁴ cm²/Vsec, and the on/off ratio was 10⁴ or more, and excellent results were obtained.

(Embodiment 4)

This embodiment is same as embodiment 3, except hat that 2,2,6,6-tetramethyl piperidinoxy radical is used instead of poly (2,2,6,6-tetramethyl piperidinoxy methacrylate) radical. As a result, a complex of a copolymer of 2,2,6,6-tetramethyl piperidinoxy radical and vinylidene fluoride/tetrafluoroethylene (copolymerization ratio 70/30) was obtained.

Next, instead of the poly (2,2,6,6-tetramethyl piperidinoxy methacrylate) radical in embodiment 1, a solution of a complex of a copolymer (copolymerization ratio 70/30) of the 2,2,6,6-tetramethyl piperidinoxy radical and vinylidene fluoride/tetrafluoroethylene obtained in the above process was similarly dripped on the element before fabrication of the channel forming layer in embodiment 1, it was dried in the air. Thus was obtained the thin film transistor using the organic layer composed of a complex of a copolymer of the 2,2,6,6-tetramethyl piperidinoxy radical and vinylidene fluoride/tetrafluoroethylene as the channel forming region.

Using this thin film transistor, the Is−Vg characteristic and Is−Vd characteristic were measured in the same manner as in embodiment 1, and the field effect mobility and on/off ratio were determined. As a result, the field effect mobility of the prepared thin film transistor was 8×10⁻⁴ cm²/Vsec, and the on/off ratio was 10³ or more, and excellent results were obtained.

Preferred embodiments of the present invention are described herein, but the thin film transistor of the present invention is not limited to these embodiments alone, and thin film transistors modified or changed from the embodiments are also included in the scope of the invention.

As described herein, the present invention brings about the thin film transistor satisfying both requirements of the carrier mobility and on/off ratio, and forming a channel forming region by using a material obtained inexpensively by a simple method.

What is claimed is:

1. A thin film transistor comprising a source region, a drain region, a channel forming region provided between said source region and said drain region, and a gate electrode provided corresponding to said channel forming region,
wherein said channel forming region is composed of an organic compound having a radical.

2. The thin film transistor according to claim 1, wherein a spin concentration of said organic compound having a radical is 10²⁰ spins/g or more.

3. The thin film transistor according to claim 1, wherein said organic compound having a radical is composed of an organic macromolecular compound having a radical.

4. The thin film transistor according to claim 1, wherein said organic compound having a radical is composed of at least one selected from the group consisting of nitroxide radical, oxygen radical, nitrogen radical, carbon radical, sulfur radical, and boron radical.
